(19) United States
(12) Patent Application Publication
(10) Pub. No.: US 2009/0090931 A1
(43) Pub. Date: Apr. 9, 2009

(54) SEMICONDUCTOR LIGHT-EMITTING DEVICE AND METHOD OF FABRICATING THE SAME

(76) Inventors: Miin-Jang CHEN, Taipei City (TW); Wen-Ching Hsu, Hsinchu City (TW); Suz-Hua Ho, Jhudong Township (TW)

Correspondence Address: Muncy, Geissler, Olds & Lowe, PLLC, P.O. BOX 1364, FAIRFAX, VA, 22038-1364, US

(21) Appl. No.: 12/244,583

(22) Filed: Oct. 2, 2008

(30) Foreign Application Priority Data
Oct. 5, 2007 (TW) 096137388

(51) Int. Cl. H01L 33/00; H01L 21/20

(52) U.S. Cl. 257/103; 438/46; 257/E33.023; 257/E21.09

(57) ABSTRACT

The invention discloses a semiconductor light-emitting device and a method of fabricating the same. The semiconductor light-emitting device according to the invention includes a substrate, a buffer layer, a corrosion-resistant film, a multi-layer structure, and an ohmic electrode structure. The buffer layer is grown on an upper surface of the substrate. The corrosion-resistant film is deposited to overlay the buffer layer The multi-layer structure is grown on the corrosion-resistant film and includes a light-emitting region. The buffer layer assists the epitaxial growth of a bottom-most layer of the multi-layer structure. The corrosion-resistant film prevents the buffer layer from being corroded by a gas during the epitaxial growth of the bottom-most layer. The ohmic electrode structure is deposited on the multi-layer structure.

### BACKGROUND OF THE INVENTION

1. Field of the Invention

The present invention relates to a semiconductor light-emitting device and, more particularly, to a semiconductor light-emitting device capable of resisting the corrosion of e.g. the NH₃ gas during the epitaxial growth thereof.

2. Description of the Prior Art

The current semiconductor light-emitting devices, such as light-emitting diodes, have been used for a wide variety of applications, e.g. optical displaying devices, traffic lights, communication devices and illumination devices. To achieve a low power consumption of the semiconductor light-emitting devices, the high quantum efficiency is required for the devices.

Please refer to FIG. 1A. In the prior art, a buffer layer 12 (e.g. a ZnO layer) can be grown between a semiconductor material layer and a substrate 10 to enhance the epitaxial quality of the semiconductor material layer and further increase the efficiency of the semiconductor light-emitting device.

Please refer to FIG. 1B. Since the epitaxial growth of the semiconductor material layer (e.g. a GaN layer) on the buffer layer 12 requires to be performed in an ambience with the NH₃ gas, if the processing temperature is too high, the NH₃ gas will corrode the ZnO layer and the epitaxial quality of the semiconductor material layer is affected. FIG. 1B illustrates a sectional view of the ZnO-based buffer layer 12 corroded by the NH₃ gas. Therefore, a protection method is necessary to prevent the buffer layer 12 from being corroded by e.g. the NH₃ gas. However, the epitaxial growth of the semiconductor material layer (e.g. a GaN layer) is not affected by the protection method.

Accordingly, the main scope of the invention is to provide a semiconductor light-emitting device capable of resisting the corrosion of e.g. the NH₃ gas during the epitaxial growth thereof.

### SUMMARY OF THE INVENTION

One scope of the invention is to provide a semiconductor light-emitting device and a fabricating method thereof.

According to an embodiment of the invention, the semiconductor light-emitting device includes a substrate, a buffer layer, a corrosion-resistant film, a multi-layer structure, and an ohmic electrode structure.

The buffer layer is grown on an upper surface of the substrate. The corrosion-resistant film is deposited to overlay the buffer layer. The multi-layer structure is grown on the corrosion-resistant film and includes a light-emitting region. The buffer layer assists the epitaxial growth of a bottom-most layer of the multi-layer structure. The corrosion-resistant film prevents the buffer layer from being corroded by a gas during the epitaxial growth of the bottom-most layer. The ohmic electrode structure is deposited on the multi-layer structure.

According to another embodiment of the invention, it is related to a method of fabricating a semiconductor light-emitting device.

First, a substrate is prepared. Subsequently, a buffer layer is grown on an upper surface of the substrate. Then, a corrosion-resistant film is deposited to overlay the buffer layer. Next, a multi-layer structure including a light-emitting region is grown on the corrosion-resistant film. The buffer layer assists the epitaxial growth of a bottom-most layer of the multi-layer structure. The corrosion-resistant film prevents the buffer layer from being corroded by a gas during the epitaxial growth of the bottom-most layer. Eventually, an ohmic electrode structure is deposited on the multi-layer structure.

Compared to the prior art, a corrosion-resistant film is deposited on the buffer layer inside the semiconductor light-emitting device according to the invention to protect the buffer layer during the epitaxial growth of a semiconductor material layer thereon so that the semiconductor material layer can be grown at a higher temperature. In addition, the buffer layer can assist the semiconductor material layer in the vertical and lateral epitaxial growth to improve the epitaxial quality of the semiconductor light-emitting device and further enhance the quantum efficiency of the semiconductor light-emitting device.

The advantage and spirit of the invention may be understood by the following recitations together with the appended drawings.

### BRIEF DESCRIPTION OF THE APPENDED DRAWINGS

FIG. 1A illustrates a sectional view of a buffer layer grown on a substrate.

FIG. 1B illustrates a sectional view of a ZnO-based buffer layer corroded by the NH₃ gas.

FIG. 2 illustrates a sectional view of a semiconductor light-emitting device according to an embodiment of the invention.

FIGS. 3A through FIG. 3E illustrate sectional views to describe a method of fabricating a semiconductor light-emitting device according to another embodiment of the invention.

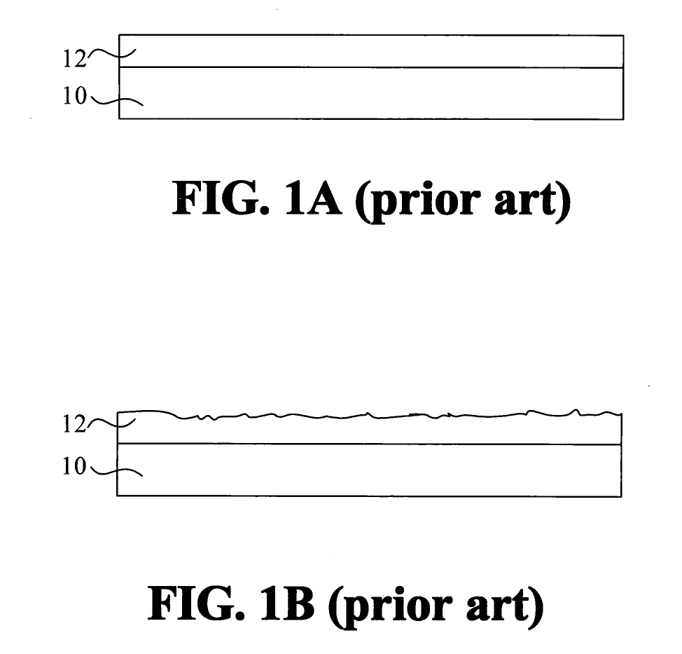

### DETAILED DESCRIPTION OF THE INVENTION

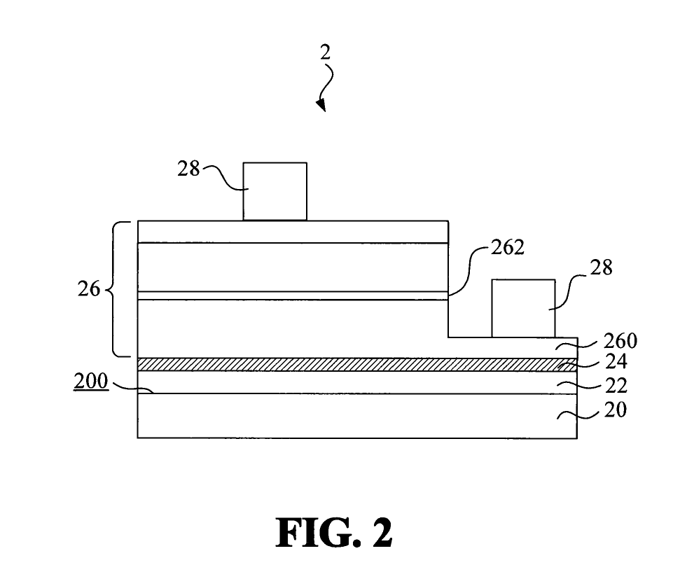

Please refer to FIG. 2. FIG. 2 illustrates a sectional view of a semiconductor light-emitting device 2 according to an embodiment of the invention.

As shown in FIG. 2, the semiconductor light-emitting device 2 includes a substrate 20, a buffer layer 22, a corrosion-resistant film 24, a multi-layer structure 26, and an ohmic electrode structure 28.

In practical applications, the substrate 20 can be made of sapphire, Si, SiC, GaN, ZnO, ScAlMgO₄, YSZ (Yttria-Stabilized Zirconia), SrCu₂O₂, LiGaO₂, LiAlO₂, GaAs and the like.

The buffer layer 22 is grown on an upper surface 200 of the substrate 20. In one embodiment, the buffer layer 22 can be directly grown on the substrate 20 and can overlay the upper surface 200 of the substrate 20. In another embodiment, the buffer layer 22 can be selectively grown on the upper surface 200 of the substrate 20 such that the upper surface 200 of the substrate 20 is partially exposed before the deposition of the multi-layer structure 26.

The corrosion-resistant film 24 is deposited to overlay the buffer layer 22. The multi-layer structure 26 is grown on the corrosion-resistant film 24 and includes a light-emitting region 262. The buffer layer 22 assists the epitaxial growth of a bottom-most layer 260 of the multi-layer structure 26.

The bottom-most layer 260 can be made of GaN, AlN, InGaN, AlGaN or AlInGaN. In one embodiment, the bottom-most layer 260 can be made of GaN. The corrosion-resistant film 24 prevents the buffer layer 22 from being corroded by a gas during the epitaxial growth of the bottom-most layer 260. The ohmic electrode structure 28 is deposited on the multi-layer structure 26.

In practical applications, the buffer layer 22 can be made of ZnO or MgₓZn₁₋ₓO, where 0<x≦1. In one embodiment, the buffer layer 22 can have a thickness in a range of 10 nm to 500 nm, and the corrosion-resistant film 24 can have a thickness in a range of 1 nm to 30 nm. To protect the buffer layer 22, the corrosion-resistant film 24 can be made of Al₂O₃ or MgO.

In practical applications, if the corrosion-resistant film 24 is made of Al₂O₃, the precursors of Al₂O₃ can be AlCl₃. AlBr₃, AlMe₃, AlEt₃, and H₂O, O₃, O₂ plasma, or an oxygen radical. If the corrosion-resistant film 24 is made of MgO, the precursors of MgO can be MgCp₂, Mg(thd)₂, and H₂O, O₃, O₂ plasma, or an oxygen radical.

In practical applications, assuming that the buffer layer 22 is made of ZnO, since the epitaxial growth of GaN requires to be performed in an ambience with the NH₃ gas (i.e. the afore-mentioned gas), the NH₃ gas will corrode ZnO if the processing temperature is too high. Therefore, to avoid the corrosion of ZnO, the corrosion-resistant film 24 can be made of Al₂O₃ and can overlay the buffer layer 22. The Al₂O₃ film can accordingly prevent the ZnO-based buffer layer 22 from being corroded by the NH₃ gas during the epitaxial growth of the bottom-most layer 260 (e.g. a GaN layer).

In one embodiment, both of the buffer layer 22 and the corrosion-resistant film 24 can be deposited by an atomic layer deposition process and/or a plasma-enhanced (or a plasma-assisted) atomic layer deposition process.

In practical applications, the growth of the buffer layer 22 can be performed at a processing temperature ranging from room temperature to 600° C. Further, the buffer layer 22 can be annealed at a temperature ranging from 400° C. to 1200° C. to increase the quality of the buffer layer 22.

In one embodiment, if the buffer layer 22 is grown by the atomic layer deposition process and is made of ZnO, the precursors of the ZnO buffer layer 22 can be ZnCl₂, ZnMe₂, ZnEt₂, and H₂O, O₃, O₂ plasma, or an oxygen radical.

In one embodiment, if the buffer layer 22 is grown by the atomic layer deposition process and is made of MgₓZn₁₋ₓO, the precursors of the MgₓZn₁₋ₓO buffer layer 22 can be ZnCl₂, ZnMe₂, ZnEt₂, MgCp₂, Mg(thd)₂, and H₂O, O₃, O₂ plasma, or an oxygen radical.

In one embodiment, to make the buffer layer 22 partially exposed, the buffer layer 22 can further be treated by a selective etching process.

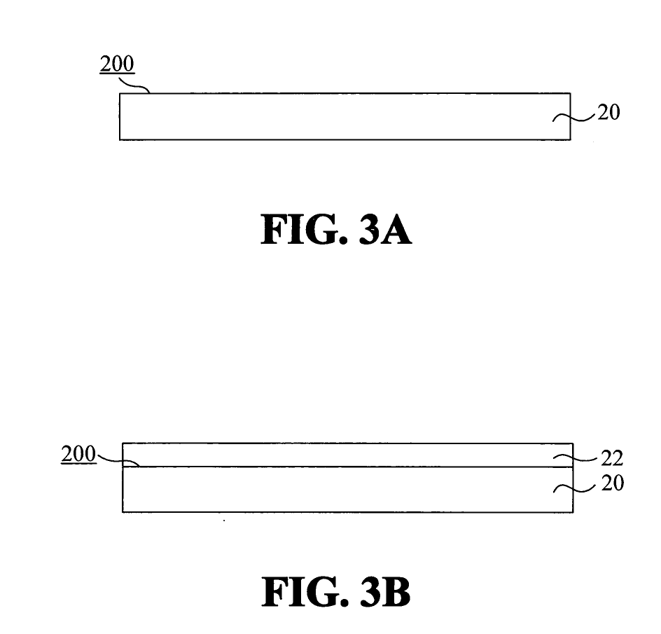

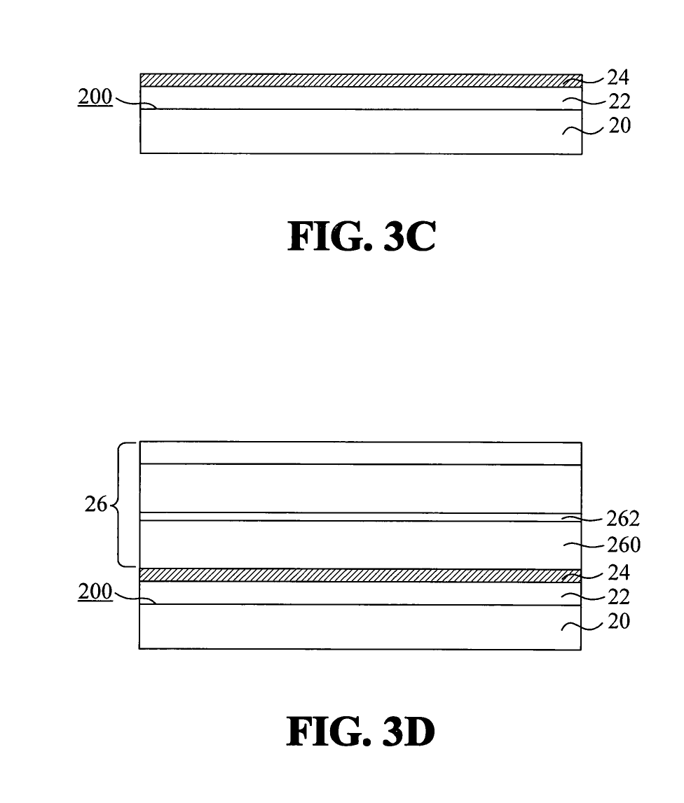

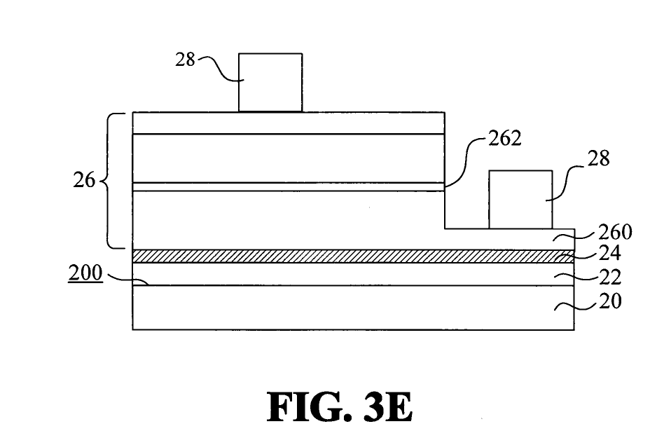

Please refer to FIGS. 3A through FIG. 3E. FIGS. 3A through FIG. 3E illustrate sectional views to describe a method of fabricating a semiconductor light-emitting device according to another embodiment of the invention.

First, a substrate 20 is prepared, as shown in FIG. 3A.

Subsequently, a buffer layer 22 can be grown on an upper surface 200 of the substrate 20 by an atomic layer deposition process and/or a plasma-enhanced (or a plasma-assisted) atomic layer deposition process, as shown in FIG. 3B.

Then, a corrosion-resistant film 24 can be deposited to overlay the buffer layer 22 by the atomic layer deposition process and/or the plasma-enhanced (or the plasma-assisted) atomic layer deposition process, as shown in FIG. 3C.

Next, a multi-layer structure 26 including a light-emitting region 262 is grown on the corrosion-resistant film 24, as shown in FIG. 3D. The buffer layer 22 assists the epitaxial growth of a bottom-most layer 260 of the multi-layer structure 26. The corrosion-resistant film 24 prevents the buffer layer 22 from being corroded by a gas during the epitaxial growth of the bottom-most layer 260.

Eventually, the multi-layer structure 26 can be selectively etched and an ohmic electrode structure 28 is deposited on the multi-layer structure 26, as shown in FIG. 3E.

Compared to the prior art, a corrosion-resistant film can be deposited on the buffer layer inside the semiconductor light-emitting device according to the invention to protect the buffer layer during the epitaxial growth of a semiconductor material layer thereon so that the semiconductor material layer can be grown at a higher temperature. In addition, the buffer layer can assist the semiconductor material layer in the vertical and lateral epitaxial growth to improve the epitaxial quality of the semiconductor light-emitting device and further enhance the quantum efficiency of the semiconductor light-emitting device.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A semiconductor light-emitting device, comprising:
a substrate;
a buffer layer, grown on an upper surface of the substrate;
a corrosion-resistant film, deposited to overlay the buffer layer;
a multi-layer structure grown on the corrosion-resistant film and comprising
a light-emitting region, wherein the buffer layer assists the epitaxial growth of a bottom-most layer of the multi-layer structure, and the corrosion-resistant film prevents the buffer layer from being corroded by a gas during the epitaxial growth of the bottom-most layer; and
an ohmic electrode structure, deposited on the multi-layer structure.

2. The semiconductor light-emitting device of claim 1, wherein the buffer layer is formed of ZnO or MgₓZn₁₋ₓO, where 0<x≦1.

3. The semiconductor light-emitting device of claim 2, wherein the bottom-most layer is made of a material selected from the group consisting of GaN, AlN, InGaN, AlGaN and AlInGaN.

4. The semiconductor light-emitting device of claim 3, wherein the gas is NH₃.

5. The semiconductor light-emitting device of claim 4, wherein the corrosion-resistant film is made of Al₂O₃ or MgO.

6. The semiconductor light-emitting device of claim 5, wherein the corrosion-resistant film is deposited by an atomic layer deposition process and/or a plasma-enhanced (or a plasma-assisted) atomic layer deposition process.

7. The semiconductor light-emitting device of claim 2, wherein the buffer layer is grown by an atomic layer deposition process and/or a plasma-enhanced (or a plasma-assisted) atomic layer deposition process.

8. The semiconductor light-emitting device of claim 7, wherein the buffer layer is grown to overlay the upper surface of the substrate.

9. The semiconductor light-emitting device of claim 7, wherein the buffer layer is selectively grown on the upper surface of the substrate such that the upper surface of the substrate is partially exposed before the deposition of the multi-layer structure.

10. The semiconductor light-emitting device of claim 9, wherein the formation of the buffer layer is also by a selective etching process.

11. The semiconductor light-emitting device of claim 1, wherein the substrate is made of a material selected from the group consisting of sapphire, Si, SiC, GaN, ZnO, ScAlMgO₄, YSZ (Yttria-Stabilized Zirconia), SrCu₂O₂, LiGaO₂, LiAlO₂, and GaAs.

12. A method of fabricating a semiconductor light-emitting device, said method comprising the steps of:
preparing a substrate;
growing a buffer layer on an upper surface of the substrate;
depositing a corrosion-resistant film overlaying the buffer layer;
growing a multi-layer structure on the corrosion-resistant film, wherein the multi-layer structure comprises a light-emitting region, the buffer layer assists he epitaxial growth of a bottom-most layer of the multi-layer structure, and the corrosion-resistant film prevents the buffer layer from being corroded by a gas during the epitaxial growth of the bottom-most layer; and
depositing an ohmic electrode structure on the multi-layer structure.

13. The method of claim 12, wherein the buffer layer is formed of ZnO or MgₓZn₁₋ₓO, where 0<x≦1.

14. The method of claim 13, wherein the bottom-most layer is made of a material selected from the group consisting of GaN, AlN, InGaN, AlGaN and AlInGaN.

15. The method of claim 14, wherein the gas is NH₃.

16. The method of claim 15, wherein the corrosion-resistant film is made of Al₂O₃ or MgO.

17. The method of claim 16, wherein the corrosion-resistant film is deposited by an atomic layer deposition process and/or a plasma-enhanced (or a plasma-assisted) atomic layer deposition process.

18. The method of claim 13, wherein the buffer layer is grown by an atomic layer deposition process and/or a plasma-enhanced (or a plasma-assisted) atomic layer deposition process.

19. The method of claim 18, wherein the buffer layer is grown to overlay the upper surface of the substrate.

20. The method of claim 18, wherein the buffer layer is selectively grown on the upper surface of the substrate such that the upper surface of the substrate is partially exposed before the deposition of the multi-layer structure.

21. The method of claim 20, wherein the formation of the buffer layer is also by a selective etching process.

22. The method of claim 12, wherein the substrate is made of a material selected from the group consisting of sapphire, Si, SiC, GaN, ZnO, ScAlMgO₄, YSZ (Yttria-Stabilized Zirconia), SrCu₂O₂, LiGaO₂, LiAlO₂, and GaAs.
